(19) United States
(12) Patent Application Publication
(10) Pub. No.: US 2014/0149057 A1
(43) Pub. Date: May 29, 2014

(54) ESTIMATING THE BATTERY LIFE OF A PORTABLE ELECTRONIC DEVICE BASED ON USAGE LOGS

(71) Applicant: APPLE INC., Cupertino, CA (US)

(72) Inventor: James H. Foster, Palo Alto, CA (US)

(73) Assignee: APPLE INC., Cupertino, CA (US)

(21) Appl. No.: 13/713,770

(22) Filed: Dec. 13, 2012

Related U.S. Application Data
(60) Provisional application No. 61/731,210, filed on Nov. 29, 2012.

(51) Int. Cl. G01R 31/36; G06F 19/00

(52) U.S. Cl. CPC G01R 31/3606; G06F 19/00
USPC 702/63

(57) ABSTRACT

The present embodiments provide a system that estimates a battery life for a portable electronic device. During operation, the system obtains a usage log containing traces of user-related system activity for the portable electronic device. Next, the system runs the usage log against a power model for the portable electronic device to determine the power consumption for the portable electronic device. Finally, the system uses the determined power consumption to estimate a battery life for the portable electronic device. In some embodiments, estimating the battery life involves determining a battery size to achieve a desired battery life for the portable electronic device.

### RELATED APPLICATIONS

This application hereby claims priority under 35 U.S.C. §119 to U.S. Provisional Application No. 61/731,210, entitled “Estimating the Battery Life of a Portable Electronic Device Based on Usage Logs,” by James H. Foster, filed 29 Nov. 2012 (Atty. Docket No.: APL-P13385US1).

### BACKGROUND

1. Field

The disclosed embodiments generally relate to tools for determining the battery life of a portable electronic device. More specifically, the disclosed embodiments relate to a system for estimating the battery life of a portable electronic device based on usage logs which contain traces of user-related system activity.

2. Related Art

Rechargeable batteries are presently used to provide power in a wide variety of portable electronic devices, including mobile phones, tablet computers, laptop computers, digital music players and remote controls. During the process of designing a portable electronic device, it is important to determine the battery size early on in the design process because the battery size is a major factor in determining the physical dimensions of the device. If the battery is too large, the resulting device will be larger and heavier than it needs to be. On the other hand, if the battery is too small, the battery life of the device will be insufficient, and a major redesign of the device may be required to increase the battery size, or additional software-engineering or hardware-engineering efforts may be required to reduce the power consumption of the device.

Hence, what is needed is a way to effectively determine the optimal size of a battery in a portable electronic device before the device is actually designed and manufactured.

### SUMMARY

The present embodiments provide a system that estimates a battery life for a portable electronic device. During operation, the system obtains a usage log containing traces of user-related system activity for the portable electronic device. Next, the system runs the usage log against a power model for the portable electronic device to determine a power consumption for the portable electronic device. Finally, the system uses the determined power consumption to estimate a battery life for the portable electronic device.

In some embodiments, estimating the battery life involves determining a battery size to achieve a desired battery life for the portable electronic device.

In some embodiments, obtaining the usage log involves recording the traces of user-related system activity while one or more users operate the portable electronic device.

In some embodiments, obtaining the usage log additionally involves developing usage profiles for one or more different types of users of the portable electronic device.

In some embodiments, the usage log contains one or more of the following: (1) timestamped system calls made by applications running on the portable electronic device; (2) processor power states for the portable electronic device; (3) radio modes for the portable electronic device; and (4) environmental conditions that influence power consumption and/or battery life for the portable electronic device.

In some embodiments, the power model for the portable electronic device specifies how power is used by power-consuming subsystems in the portable electronic device.

In some embodiments, determining the power consumption involves determining power consumption for each of the power-consuming subsystems in the portable electronic device, thereby enabling a system designer to determine which power-consuming subsystems to modify to effectively reduce power consumption.

In some embodiments, running the usage log against the power model involves parsing the usage log to determine which power-consuming subsystems are driven by the usage log.

In some embodiments, the power-consuming subsystems in the portable electronic device include one or more of the following: a display; a radio transceiver; a processor; a memory; and a speaker.

### BRIEF DESCRIPTION OF THE FIGURES

FIG. 1 illustrates a portable electronic device in accordance with the disclosed embodiments.

FIG. 2 presents a flow chart illustrating the process of gathering usage logs of user-related system activity in accordance with the disclosed embodiments.

FIG. 3 illustrates a system for estimating a battery life for a portable electronic device in accordance with the disclosed embodiments.

FIG. 4 presents a flow chart illustrating the process of estimating a battery life for a portable electronic device in accordance with the disclosed embodiments.

### DETAILED DESCRIPTION

The following description is presented to enable any person skilled in the art to make and use the present embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present embodiments. Thus, the present embodiments are not limited to the embodiments shown, but are to be accorded the widest scope consistent with the principles and features disclosed herein.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disk drives, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium. Furthermore, the methods and processes described below can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

### Overview

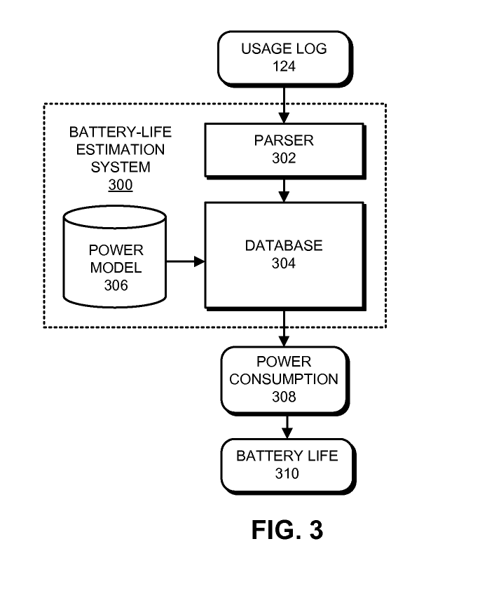

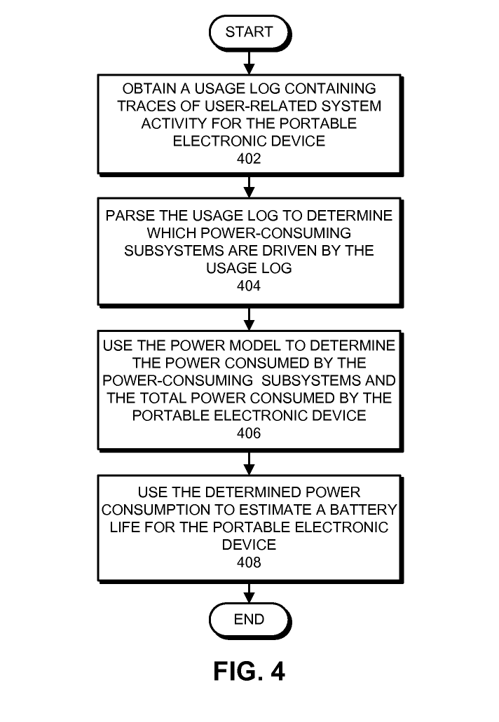

The disclosed embodiments generally relate to a software tool that allows a system designer to model the major subsystems in a portable electronic device and their associated power consumption. This tool operates by first obtaining real-life usage logs associated with different types of users of the portable electronic device. Next, the system runs the usage logs on a power model for the portable electronic device to determine a power consumption for the portable electronic device. The determined power consumption is then used to estimate a battery life or to determine an optimal battery size for the portable electronic device. Details of this software tool are described in more detail below with reference to FIGS. 3-4, but first we describe the internal structure of an exemplary portable electronic device.

### Portable Electronic Device

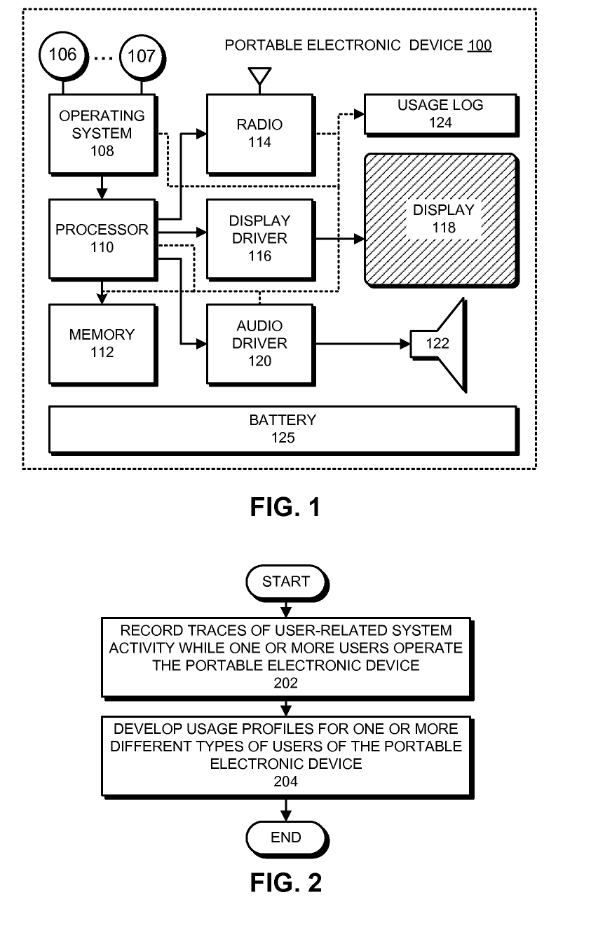

FIG. 1 illustrates the structure of an exemplary portable electronic device 100 in accordance with the disclosed embodiments. Portable electronic device 100 can generally include any type of battery-operated electronic device, including a laptop computer, a media player (such as an MP3 player), an appliance, a peripheral device (such as a trackpad, a touchscreen, a display, a mouse, a camera, a keyboard, a user-interface device, etc.), a subnotebook/netbook, a tablet computer, a smartphone, a cellular telephone, a piece of testing equipment, a network appliance, a set-top box, a personal digital assistant (PDA), a toy, a controller, a digital signal processor, a game console, a computational engine within an appliance, a consumer-electronic device, a portable computing device, a personal organizer, and/or another battery-powered electronic device.

Although specific components are used to describe portable electronic device 100, in alternative embodiments, different components and/or subsystems may be present in portable electronic device 100. For example, portable electronic device 100 may include one or more additional processors, memory, and/or displays. Additionally, one or more of the subsystems or components may not be present in portable electronic device 100. Moreover, in some embodiments, portable electronic device 100 may include one or more additional subsystems that are not shown in FIG. 1. For example, portable electronic device 100 can additionally include: a data collection subsystem, an alarm subsystem, a media processing subsystem, and/or an input/output (I/O) subsystem.

As illustrated in FIG. 1, portable electronic device 100 runs a number of applications 106-107 on behalf of a user of portable electronic device 100. These applications can generally include any type of application which can be run on portable electronic device 100, such as a mail program, a web browser or a video player.

The execution of applications 106-107 is controlled by an operating system 108, which causes applications 106-107 to be executed on a processor 110 which contains one or more processor cores. While executing applications 106-107 and operating system 108, processor 110 accesses code and data stored in memory 112, wherein memory 112 can include any type of volatile or non-volatile computer-based memory.

During operation, portable electronic device 100 can make calls to a radio 114 to perform various communication operations. Moreover, radio 114 can provide a number of different types of communication technologies, including the second-generation wireless telephone technology (2G) and the global system for mobile communications (GSM) standard, the third-generation mobile telecommunications technology (3G), the high-speed packet access (HSPA) protocol, the long term evolution (LTE) standard, voice calls, and other types of data transmissions. Also, radio 114 can provide a number of different transmit powers. Note that each of these different types of communication technologies and transmit powers will cause different power-consumption patterns.

During operation, portable electronic device 100 can also cause display driver 116 to produce graphical output for a display 118 for the portable electronic device. For example, this graphical output can cause display 118 to be in a dim state or a very bright state, or can cause display 118 to output a still image or a video. Note that each of these different types of graphical output will have different power-consumption characteristics.

Similarly, operating system 108 and processor 110 can cause an audio driver 120 to produce audio output for an audio output device 122 (e.g., a speaker). This audio output may be very quiet or very loud, thereby resulting in different types of power-consumption patterns.

Portable electronic device 100 also includes a rechargeable battery 125 which provides power to the components within portable electronic device 100.

### User Logs

Note that each of the hardware components illustrated in FIG. 1 consumes power. Moreover, during a data-gathering mode, operating system 108 generates a usage log 124 containing traces of user-related system activity. For example, usage log 124 can contain one or more of the following: (1) timestamped system calls made by applications running on the portable electronic device; (2) power states for processor 110 (Note that modern processors typically provide a number of different power states associated with different levels of performance. For example, processors often enter power-saving modes during periods of low activity and may also enter an over-clocked high-power mode during periods of peak activity.); (3) operational modes for radio 114; and (4) environmental conditions that influence power consumption and/or battery life for the portable electronic device. (For example, temperature is an environmental condition which greatly affects battery life.)

FIG. 2 presents a flow chart illustrating the process of gathering usage logs of user-related system activity in accordance with the disclosed embodiments. During operation, the system records traces of user-related system activity while one or more users operate the portable electronic device (step 202). During this process, the system can develop usage profiles for one or more different types of users of the portable electronic device (step 204). For example, some users may be “road warriors” who make heavy demands on the computational and communication resources of portable electronic device 100, whereas other users may be “vacationing retirees” who occasionally make telephone calls and send emails.

### System for Estimating Battery Life

FIG. 3 illustrates a system 300 for estimating a battery life for a portable electronic device and FIG. 4 presents a corresponding flow chart for operations performed by system 300 in accordance with the disclosed embodiments. During operation, system 300 obtains a usage log 124 as described above containing traces of user-related system activity (step 402 in FIG. 4). Next, a parser 302 parses usage log 124 to determine which power-consuming subsystems are driven by the activities recorded in usage log 124 (step 404 in FIG. 4).

Next, the system uses a database 304 to access a power model 306 for portable electronic device 100 to determine how power is used by various power-consuming subsystems within portable electronic device 100 and also to determine the total power consumption 308 for portable electronic device 100 (step 406 in FIG. 4). In some embodiments, determining the power consumption 308 also involves determining power consumption for each of the power-consuming subsystems in the portable electronic device. This enables a system designer to determine which power-consuming subsystems to modify to effectively reduce power consumption. For example, the power-consumption data may indicate that the display is consuming an inordinate amount of power. In this case, the system designer can, for example, modify the backlight driver for the display to reduce the power consumption of the display.

Finally, the system uses the determined power consumption 308 to estimate a battery life 310 for the portable electronic device 100 (step 408 in FIG. 4). As mentioned above, determining the battery life 310 can also involve determining a battery size to achieve a desired battery life for the portable electronic device.

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A method for estimating a battery life for a portable electronic device, comprising:
obtaining a usage log containing traces of user-related system activity for the portable electronic device;
running the usage log against a power model for the portable electronic device to determine a power consumption for the portable electronic device; and
using the determined power consumption to estimate a battery life for the portable electronic device.

2. The method of claim 1, wherein estimating the battery life involves determining a battery size to achieve a desired battery life for the portable electronic device.

3. The method of claim 1, wherein obtaining the usage log involves recording the traces of user-related system activity while one or more users operate the portable electronic device.

4. The method of claim 3, wherein obtaining the usage log additionally involves developing usage profiles for one or more different types of users of the portable electronic device.

5. The method of claim 1, wherein the usage log contains one or more of the following:
timestamped system calls made by applications running on the portable electronic device;
processor power states for the portable electronic device;
radio modes for the portable electronic device; and
environmental conditions that influence power consumption and/or battery life for the portable electronic device.

6. The method of claim 1, wherein the power model for the portable electronic device specifies how power is used by power-consuming subsystems in the portable electronic device.

7. The method of claim 6, wherein determining the power consumption involves determining power consumption for each of the power-consuming subsystems in the portable electronic device, thereby enabling a system designer to determine which power-consuming subsystems to modify to effectively reduce power consumption.

8. The method of claim 6, wherein running the usage log against the power model involves parsing the usage log to determine which power-consuming subsystems are driven by the usage log.

9. The method of claim 6, wherein the power-consuming subsystems in the portable electronic device include one or more of the following:
a display;
a radio transceiver;
a processor;
a memory; and
a speaker.

10. A system for estimating a battery life for a portable electronic device, comprising:
a data-input mechanism configured to access a usage log containing traces of user-related system activity for the portable electronic device; and
a power model configured to determine a power consumption for the portable electronic device based on the usage log; and
an estimation mechanism configured to use the determined power consumption to estimate a battery life for the portable electronic device.

11. The system of claim 10, wherein while estimating the battery life, the estimation mechanism is configured to determine a battery size to achieve a desired battery life for the portable electronic device.

12. The system of claim 10, further comprising a data-gathering mechanism configured to record the traces of user-related system activity while one or more users operate the portable electronic device.

13. The system of claim 12, wherein the data-gathering mechanism is configured to develop usage profiles for one or more different types of users of the portable electronic device.

14. The system of claim 10, wherein the usage log contains one or more of the following:
timestamped system calls made by applications running on the portable electronic device;
processor power states for the portable electronic device;
radio modes for the portable electronic device; and
environmental conditions that influence power consumption and/or battery life for the portable electronic device.

15. The system of claim 10, wherein the power model specifies how power is used by power-consuming subsystems in the portable electronic device.

16. The system of claim 15, wherein while determining the power consumption, the power model is configured to determine a power consumption for each of the power-consuming subsystems in the portable electronic device, thereby enabling a system designer to determine which power-consuming subsystems to modify to effectively reduce power consumption.

17. The system of claim 15, wherein the power model is configured to parse the usage log to determine which power-consuming subsystems are driven by the usage log.

18. The system of claim 17, wherein the power-consuming subsystems in the portable electronic device include one or more of the following:
a display;
a radio transceiver;
a processor;
a memory; and
a speaker.

19. A computer-readable storage medium storing instructions that when executed by a computer cause the computer to perform a method for estimating a battery life for a portable electronic device, the method comprising:
obtaining a usage log containing traces of user-related system activity for the portable electronic device;
running the usage log against a power model for the portable electronic device to determine a power consumption for the portable electronic device; and
using the determined power consumption to estimate a battery life for the portable electronic device.

20. The computer-readable storage medium of claim 19, wherein estimating the battery life involves determining a battery size to achieve a desired battery life for the portable electronic device.

21. The computer-readable storage medium of claim 19, wherein obtaining the usage log involves recording the traces of user-related system activity while one or more users operate the portable electronic device.

22. The computer-readable storage medium of claim 21, wherein obtaining the usage log additionally involves developing usage profiles for one or more different types of users of the portable electronic device.

23. The computer-readable storage medium of claim 19, wherein the usage log contains one or more of the following:
timestamped system calls made by applications running on the portable electronic device;
processor power states for the portable electronic device;
radio modes for the portable electronic device; and
environmental conditions that influence power consumption and/or battery life for the portable electronic device.

24. The computer-readable storage medium of claim 19, wherein the power model for the portable electronic device specifies how power is used by power-consuming subsystems in the portable electronic device.

25. The computer-readable storage medium of claim 24, wherein determining the power consumption involves determining power consumption for each of the power-consuming subsystems in the portable electronic device, thereby enabling a system designer to determine which power-consuming subsystems to modify to effectively reduce power consumption.

26. The computer-readable storage medium of claim 24, wherein running the usage log against the power model involves parsing the usage log to determine which power-consuming subsystems are driven by the usage log.

27. The computer-readable storage medium of claim 24, wherein the power-consuming subsystems in the portable electronic device include one or more of the following:
a display;
a radio transceiver;
a processor;
a memory; and
a speaker.
